(19) United States
(12) Patent Application Publication
(10) Pub. No.: US 2023/0413626 A1
(43) Pub. Date: Dec. 21, 2023

(54) SEMICONDUCTOR DEVICE, DISPLAY DEVICE, PHOTOELECTRIC CONVERSION DEVICE, ELECTRONIC DEVICE AND IMAGE FORMING APPARATUS

(71) Applicant: CANON KABUSHIKI KAISHA, Tokyo (JP)

(72) Inventor: KAZUYA NOTSU, Kanagawa (JP)

(21) Appl. No.: 18/326,216

(22) Filed: May 31, 2023

(30) Foreign Application Priority Data
Jun. 8, 2022 (JP) 2022-092935

(51) Int. Cl. H10K 59/131; H10K 59/80

(52) U.S. Cl. CPC H10K 59/131; H10K 59/8794

(57) ABSTRACT

A semiconductor device, includes: a substrate having an effective element area on which a functional element is disposed, and a peripheral area that surrounds the effective element area, the substrate having a terminal portion in at least a portion of the peripheral area a first wiring board connected to the substrate via the terminal portion of the substrate; and a drive circuit chip having a drive circuit, and connected to the first wiring board, wherein a thermal conductivity of the first wiring board is equal to or higher than a thermal conductivity of the substrate and of the drive circuit chip.

### BACKGROUND OF THE INVENTION

### Field of the Invention

The present invention relates to a semiconductor device, a display device, a photoelectric conversion device, an electronic device, and an image forming apparatus.

### Description of the Related Art

There is an ongoing increase in the number of external output terminals in display devices that have for instance a drive circuit chip, a display device (semiconductor device) and a light-transmitting plate, with a view to improving definition and processing speed. In conventional wire bonding connection it is difficult to reduce connection pitch, and a problem arises in that the drive circuit chip and the display device become larger as the number of external output terminals increases.

Therefore, techniques for flip-chip mounting of drive circuit chips onto display devices are drawing attention. In flip-chip mounting, joining pads of reduced size are connected to each other, in a semiconductor process, via connecting portions such as bumps; as a result the pitch of output terminals can be made narrower than in wire bonding connection.

Japanese Patent Application Publication No. 2008-165034 discloses a display device in which a drive circuit chip and a display device are flip-chip mounted via a connecting portion formed of a conductive material.

Japanese Patent Application Publication No. 2017-103153 discloses an organic EL module provided with a heat dissipation member for dissipating heat generated by a drive circuit chip and a functional unit that includes an organic EL element.

In the display device disclosed in Japanese Patent Application Publication No. 2008-165034, however, the drive circuit chip is flip-chip mounted, and accordingly the distance between the drive circuit chip and the display device is short. Heat generated in the drive circuit chip flows easily as a result to the display device. Devices the characteristics whereof deteriorate readily on account of heat, such as organic semiconductor devices, are problematic in that image quality (imaging quality or display quality) deteriorates on account of the heat generated in drive circuit chips.

The drive circuit chip of the organic EL module disclosed in Japanese Patent Application Publication No. 2017-103153 is mounted on the same main surface, of the substrate, as that of the functional unit, and hence it is difficult to reduce transfer of heat from the drive circuit chip to the substrate.

### SUMMARY OF THE INVENTION

The present invention provides a technique for reducing heat transfer from a drive circuit chip to an element substrate of a semiconductor device, and for reducing impairment of the characteristics of the semiconductor device.

A semiconductor device according to the present invention includes: a substrate having an effective element area on which a functional element is disposed, and a peripheral area that surrounds the effective element area, the substrate having a terminal portion in at least a portion of the peripheral area a first wiring board connected to the substrate via the terminal portion of the substrate; and a drive circuit chip having a drive circuit, and connected to the first wiring board, wherein a thermal conductivity of the first wiring board is equal to or higher than a thermal conductivity of the substrate and of the drive circuit chip.

Further features of the present invention will become apparent from the following description of exemplary embodiments with reference to the attached drawings.

### BRIEF DESCRIPTION OF THE DRAWINGS

FIG. 1A and FIG. 1B are schematic diagrams illustrating a semiconductor device according to Embodiment 1;

FIG. 2A to FIG. 2F are diagrams for explaining a method for producing a semiconductor device according to Embodiment 1;

FIG. 3A and FIG. 3B are schematic diagrams illustrating a semiconductor device according to Embodiment 2;

FIG. 4 is a schematic diagram illustrating a semiconductor device according to Embodiment 3;

FIG. 5 is a schematic diagram illustrating a semiconductor device according to Embodiment 4;

FIG. 6 is a schematic diagram illustrating a semiconductor device according to Embodiment 5;

FIG. 7 is a schematic diagram illustrating a semiconductor device according to Embodiment 6;

FIG. 8 is a schematic diagram illustrating a semiconductor device according to Embodiment 7;

FIG. 9 is a schematic diagram illustrating a semiconductor device according to Embodiment 8;

FIG. 10 is a schematic diagram illustrating a display device according to Embodiment 9;

FIG. 11A and FIG. 11B are schematic diagrams illustrating an imaging device and an electronic device according to Embodiment 9;

FIG. 12A and FIG. 12B are schematic diagrams illustrating a display device according to Embodiment 9;

FIG. 13A and FIG. 13B are schematic diagrams illustrating a lighting device and a moving body according to Embodiment 9;

FIG. 14A and FIG. 14B are schematic diagrams illustrating a wearable device according to Embodiment 9; and

FIG. 15A to FIG. 15C are schematic diagrams illustrating an image forming apparatus according to Embodiment 9.

### DESCRIPTION OF THE EMBODIMENTS

Embodiments for carrying out the present invention will be explained below with reference to accompanying drawings. In the explanation and drawings that follow, configurations shared across the drawings are denoted by shared reference symbols. Therefore, shared configurations will be explained while interchangeably referring to multiple drawings; also, explanations bearing on configurations denoted by shared reference symbols may be omitted as appropriate. In the present specification an organic semiconductor device is a device that utilizes an organic substance exhibiting properties as a semiconductor; a representative such device may be for instance a display device such as an organic EL display.

### Embodiment 1

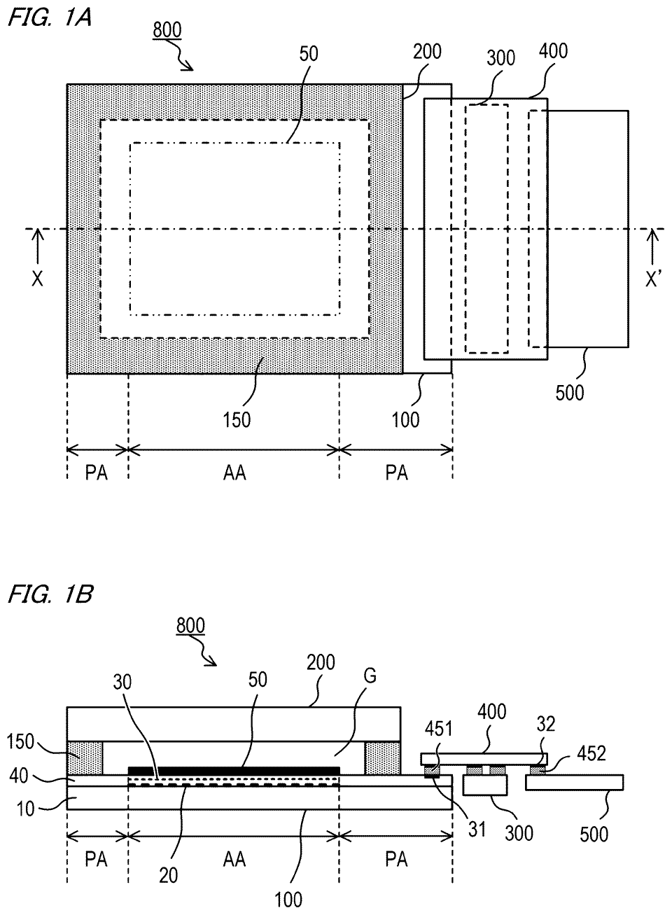

FIG. 1A illustrates a perspective-view diagram of a semiconductor device 800, with a main surface of an element substrate 100 in a plan view. Specifically, FIG. 1A illustrates an arrangement where the semiconductor device 800 is viewed from a direction perpendicular to the main surface of the element substrate 100 (normal direction of the main surface; stacking direction). A counter substrate 200, a wiring board 400 (first wiring board), and a wiring board 500 (second wiring board) are disposed side by side on the main surface side of the element substrate 100; herein overlapping portions hidden on the side of the element substrate 100 are denoted by a dashed line or a chain line.

The counter substrate 200 is disposed, in a plan view of the main surface of the element substrate 100, so as to overlap a functional element 50 included in the element substrate 100. The direction in which the counter substrate 200 faces the element substrate 100 and the functional element 50 (opposing direction) is a direction perpendicular to the main surface of the element substrate 100.

The element substrate 100 has an effective element area AA and a peripheral area PA that surrounds the effective element area AA. Effective elements (functional elements) are disposed in the effective element area AA. The effective element area AA can be herein a quadrilateral area. The diagonal length of the effective element area AA is for instance from 5 to 50 mm.

The peripheral area PA may include a peripheral circuit area (not shown) having a peripheral circuit disposed therein. In a case where the semiconductor device 800 is a display device, the peripheral circuit includes include for instance a drive circuit for driving an effective pixel and a processing circuit such as a DAC (digital-to-analog conversion circuit) for processing signals that are inputted to the effective pixel. The peripheral area PA may include a non-effective element area (not shown) positioned outside the effective element area AA and in which a non-effective element is provided. A non-effective element is herein an element that does not function as an effective element, and may be for instance a dummy element, a reference element, a test element or a monitor element.

A resin layer 150, which is provided in the peripheral area PA of the element substrate 100, bonds the counter substrate 200 and the element substrate 100. The wiring board 400 is electrically joined to the element substrate 100 in the peripheral area PA. A drive circuit chip 300 is disposed overlapping the wiring board 400 in a plan view of the main surface of the element substrate 100. The wiring board 500 is electrically joined to the wiring board 400. The wiring board 500 is disposed overlapping part of the wiring board 400 in a plan view of the main surface of the element substrate 100.

FIG. 1B is an X-X′ cross-sectional diagram of the semiconductor device 800 illustrated in FIG. 1A. The semiconductor device 800 includes the element substrate 100, the resin layer 150, the counter substrate 200, the wiring board 400, the drive circuit chip 300 and the wiring board 500. In the example of FIG. 1B, the element substrate 100, the drive circuit chip 300, and the wiring board 500 are connected by the wiring board 400, and are disposed so that the surfaces thereof connected to the wiring board 400 lie in a common plane.

The element substrate 100 has a substrate 10, semiconductor elements 20, a wiring layer 30, terminal portion 31, an interlayer insulating layer 40 and the functional element 50. The semiconductor elements 20, the wiring layer 30, and the functional element 50 are provided in the effective element area AA of the element substrate 100. The terminal portion 31 and a peripheral circuit (not shown) are provided in the peripheral area PA surrounding the effective element area AA.

The wiring board 400 is electrically connected to the element substrate 100, at a terminal portion 32 of the wiring board 400, via a joining member 451 and the terminal portion 31 of the element substrate 100. The drive circuit chip 300 and the wiring board 500 are electrically connected to the wiring board 400 via the terminal portion 32 and a joining member 452 of the wiring board 400. The joining member 451 and the joining member 452 are conductive members, such as solder or ACFs (Anisotropic Conductive Films).

The counter substrate 200 is disposed facing the element substrate 100, so as to cover part of the effective element area AA and the peripheral area PA, for the purpose of protecting the surface of the functional element 50 and preventing intrusion of dirt. The resin layer 150 is provided in the peripheral area PA of the element substrate 100, and bonds the element substrate 100 and the counter substrate 200.

A gap G is provided between the element substrate 100 and the counter substrate 200. With a view to suppressing intrusion of moisture into the functional element 50, the gap G may be filled with a first resin that is the same material as that of the resin layer 150, or with a second resin that is different from the first resin. The first resin and the second resin that fill the gap G may be any material, so long as the material is transparent, and may be for instance an acrylic resin or an epoxy resin. The gap G elicits a light-condensing function in a case where the functional element 50 is a display element and has a microlens on the element surface.

The substrate 10 contains a semiconductor such as single-crystal silicon. The semiconductor elements 20 include transistors or diodes. Part of the semiconductor elements 20 is provided in the substrate 10. The wiring layer 30 includes multilayer wiring layers for instance in the form of aluminum layers or copper layers, and plugs such as via plugs or contact plugs. The terminal portion 31 may be formed in the same layer as the wiring layer 30.

The interlayer insulating layer 40 may include multiple interlayers insulating layers. The interlayer insulating layer 40 includes for instance a silicon oxide layer, a silicon nitride layer, or a silicon carbide layer. Silicon oxynitride and silicon carbonitride contain nitrogen and silicon as main elements, and accordingly can be regarded as kinds of silicon nitride.

The functional element 50 is provided in the effective element area AA of the element substrate 100. The functional element 50 is for instance a display element or a photoelectric conversion element. The display element is for instance an EL element in an ELD (electroluminescence display), a liquid crystal element in an LCD (liquid crystal display) or a reflective element in a DMD (digital mirror device).

The functional element 50 is connected to the wiring layer 30 by way of vias (not shown) provided in the interlayer insulating layer 40, and is electrically connected to the semiconductor elements 20 via the wiring layer 30. For instance a passivation film for suppressing intrusion of moisture, oxygen or the like, a color filter layer and a lens structure, can be provided on the functional element 50.

The resin layer 150 is provided in the peripheral area PA of the element substrate 100, such that the counter substrate 200 is bonded to the element substrate 100 by the resin layer 150. A light-transmitting material such as glass or acrylic can be used as the material of the counter substrate 200. Alkali-free glass is suitably used as the material of the counter substrate 200. The thickness of the counter substrate 200 can be for instance set to 0.7 mm.

Preferably, an anti-reflection film (AR film for short) is formed on either main surface, or on both main surfaces, of the counter substrate 200. In a case where the functional element 50 is a photoelectric conversion element, incidence light efficiency increases through formation of an AR film. In a case where the functional element 50 is a display element, display light can be efficiently extracted through formation of an AR film.

The terminal portion 31 is disposed in at least a portion of the peripheral area PA of the element substrate 100. The wiring board 400 connected to the drive circuit chip 300 and the wiring board 500 is joined to the terminal portion 31 of the element substrate 100 via the joining member 451.

The drive circuit chip 300 is a semiconductor chip, provided with a drive circuit, that is connected to the wiring board 400. The drive circuit chip 300 is connected to the wiring board 400 while being separated from the element substrate 100. A joining electrode (not shown) such as Au (gold) bumps or Cu (copper) bumps is provided on the surface at which the drive circuit chip 300 is joined to the wiring board 400.

Preferably, a material having a thermal conductivity equal to or higher than that of the drive circuit chip 300 and of the element substrate 100 is used as the material of the wiring board 400. For instance metallic materials such as gold, silver, copper or aluminum in which an insulating material and a conductive material are patterned on a substrate surface, or ceramic materials such as aluminum nitride or silicon nitride in which a conductive material is patterned on a substrate surface, can be used herein, as the material of the wiring board 400. More preferably, a silicon substrate is used as the wiring board 400.

The wiring board 500 is a flexible circuit board such as a glass epoxy board or a polyimide film having a wiring pattern provided thereon. A joining electrode (not shown) such as Au bumps or Cu bumps is provided on the surface at which the wiring board 500 is joined to the wiring board 400.

The joining member 451 of the wiring board 400 and the element substrate 100, as well as the joining members 452 of the wiring board 400 with the drive circuit chip 300 and the wiring board 500, are ACFs (anisotropic conductive films) or solder. A joining electrode (terminal portion 32) of the wiring board 400 is electrically joined to a joining electrode of the element substrate (wiring layer 30), the drive circuit chip 300, and the wiring board 500 for instance by thermocompression joining.

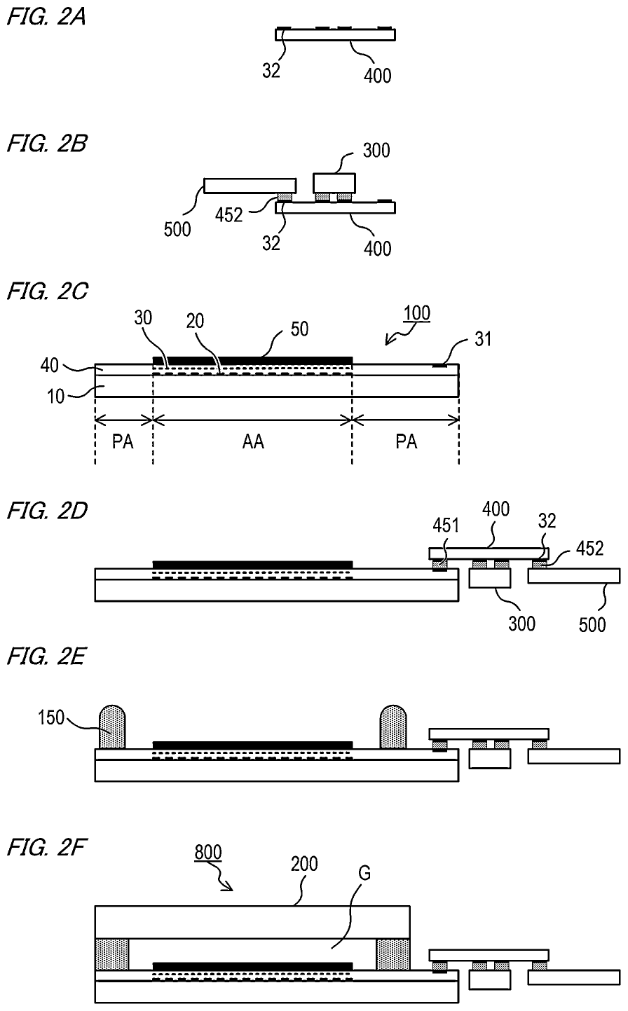

A method for producing an organic EL display device, being an example of the semiconductor device 800 according to the embodiment, will be explained next with reference to FIG. 2A to FIG. 2F. FIG. 2A illustrates a cross-sectional diagram of the wiring board 400. Electrical wiring is formed on the wiring board 400 and opening pads (not shown) for electrical connection are produced, for instance as a result of a semiconductor process. The terminal portion 32 such as Au bumps and Cu bumps is formed on the opening pads for instance by electroplating.

In FIG. 2B, the wiring board 400 is connected to the drive circuit chip 300 and the wiring board 500. Joining electrodes (not shown) for connection to the wiring board 400 are formed on the drive circuit chip 300 and the wiring board 500. The joining electrodes of the drive circuit chip 300 and the wiring board 500 are joined so as to oppose the terminal portion 32 of the wiring board 400.

The joining method may be for instance thermocompression joining using an ACF (anisotropic conductive film), solder joining or ultrasonic joining. The joining electrode (terminal portion 32) of the wiring board 400 is electrically joined to the joining electrode of the drive circuit chip 300 and the wiring board 500 by thermocompression joining or by ultrasonic compression joining. The wiring board 500 is for instance a flexible circuit board in which a copper wiring pattern is formed on a polyimide base material.

FIG. 2C illustrates a cross-sectional diagram of the element substrate 100 once the production process thereof is complete. The element substrate 100 includes the substrate 10. For instance silicon can be used as the material of the substrate 10. Semiconductor elements 20 such as transistors are formed on the main surface of the substrate 10.

The interlayer insulating layer 40 is formed on the main surface, of the substrate 10, having the semiconductor elements 20 formed thereon. For instance silicon oxide, silicon nitride or silicon carbide is used as the material of the interlayer insulating layer 40. Contact plugs (not shown) electrically connected to the semiconductor elements 20 are disposed in the interlayer insulating layer 40. A conductive member such as tungsten is embedded in the contact plugs. The wiring layer 30 that is electrically connected to the semiconductor elements 20 via contact plugs is provided in the interior of the interlayer insulating layer 40. A metal member such as aluminum or copper is used as the material of the wiring layer 30. A barrier metal such as Ti, Ta, TiN or TaN may be provided at the interface between the interlayer insulating layer 40 and the wiring layer 30, for the purpose of suppressing metal diffusion into the interlayer insulating layer 40.

The terminal portion 31 is formed in the peripheral area PA of the substrate 10. The wiring layer 30 is made up of a plurality of layers, and the terminal portion 31 is formed in the same layer as any one of such wiring layers 30. An opening resulting from removing the interlayer insulating layer 40 is provided on the terminal portion 31, thus enabling connection of the terminal portion 31 to an external terminal.

For instance an organic EL element is provided, as the functional element 50, on the interlayer insulating layer 40, in the effective element area AA. The organic EL element is electrically connected to the wiring layer 30 by way of through-holes. The organic EL element is made up of a pixel electrode, a counter electrode, and an organic light-emitting layer that is provided between the pixel electrode and the counter electrode.

A hole injection layer and a hole transport layer may be formed between the organic light-emitting layer and the pixel electrode, for the purpose of facilitating injection and transport of holes from the pixel electrode. An electron transport layer and an electron injection layer may be formed between the organic light-emitting layer and the counter electrode, for the purpose of facilitating injection and transport of electrons from the counter electrode.

A passivation film for sealing may be formed on the organic EL element which is the functional element 50, with a view to suppressing intrusion of moisture. A color filter layer and a lens structure for improving light extraction efficiency may be provided on the passivation film.

FIG. 2D is a cross-sectional diagram illustrating the element substrate 100 connected to the wiring board 400, the drive circuit chip 300 and the wiring board 500 illustrated in FIG. 2B. Herein an ACF is affixed, as a joining member 451, onto on the terminal portion 31 of the element substrate 100. A joining electrode (terminal portion 32) formed on the main surface of the wiring board 400 is thermocompression joined to a joining electrode (terminal portion 31) of the element substrate 100 via the joining member 451. The thermocompression joining temperature is preferably set for instance to 100° C. in order to preclude thermal deterioration of the organic EL element (functional element 50).

The ACF used as the joining member 451 contains conductive particles in an epoxy resin binder. The terminal portion 31 and the wiring board 400 are electrically joined by the conductive particles. Joining of the joining electrode is not limited to thermocompression joining, and may involve joining by ultrasonic waves. In ultrasonic joining, the temperature at the time of pressure-joining can be made lower than in the case of thermocompression joining; as a result, this allows reducing deterioration of the organic EL material.

An underfill resin may be injected into the junction of the element substrate 100 and the wiring board 400, the junction of the drive circuit chip 300 and the wiring board 400, and the junction of the wiring board 400 and the wiring board 500. The connection between the substrates can be made firmer, and the durability of the semiconductor device 800 can be enhanced, through injection of the underfill resin.

FIG. 2E illustrates a cross-sectional diagram with the element substrate 100, having the resin layer 150 applied onto the peripheral area PA. The resin layer 150 is applied so as to surround the effective element area AA. The resin layer 150 is formed to a thickness such that the element substrate 100 and the counter substrate 200 do not come into contact with each other. Therefore, the resin used in the resin layer 150 preferably has a viscosity of 10000 mPa·s or higher. The thickness of the resin layer 150 can be easily controlled by using a resin having kneaded thereinto a spacer in the form of glass beads or resin beads of predetermined size. An arbitrary resin material such as an epoxy resin or an acrylic resin is used as the material of the resin layer 150. For instance the resin layer 150 can be formed through application, by dispensing, of an epoxy resin having kneaded thereinto resin beads from 10 to 100 μm, preferably of 30 μm.

FIG. 2F illustrates a cross-sectional diagram of a state resulting from bonding the counter substrate 200, by way of resin layer 150, with bonding through curing, so that the counter substrate 200 opposes the main surface of the element substrate 100. At the time of bonding of the counter substrate 200 onto the to the element substrate 100, the resin material of the resin layer 150 spreads horizontally, on account of the load of the counter substrate 200. The resin layer 150 may be formed through curing of the resin material with ultraviolet rays, in a state where the bonding load exerted on the counter substrate 200 is controlled so that the resin material does not wet and spread over the effective pixel area AA of the element substrate 100. An arbitrary substrate such as a glass or acrylic substrate can be used as the counter substrate 200, so long as the substrate is transparent; for instance alkali-free glass can be used herein. Preferably, the thickness of the resin layer 150 after bonding of the counter substrate 200 is from 10 μm to 100 μm. The organic EL display device is completed as a result of the above steps.

In Embodiment 1 above, the element substrate 100 and the drive circuit chip 300 are connected via the wiring board 400; as a result, the distance between the drive circuit chip 300 and the element substrate 100 can be increased, such that transfer of heat from the drive circuit chip 300 to the element substrate 100 is reduced. In addition, the heat dissipation characteristic of the semiconductor device 800 is improved, since the heat from the drive circuit chip 300 can be dumped from the wiring board 400. Characteristic deterioration caused by heat from the drive circuit chip 300 can be reduced in the semiconductor device 800 in a case in particular where the functional element 50 is an organic EL element that is susceptible to heat.

In Embodiment 1 an instance has been explained in which the drive circuit chip 300 is flip-chip mounted; however, the present embodiment is not limited to flip-chip mounting, and can be applied to other mounting methods such as wire bonding. By connecting the drive circuit chip 300 to the element substrate 100 via the wiring board 400, heat generated in the drive circuit chip 300 is less readily transmitted to the element substrate 100. In a case where the number of external connection terminals is large and flip-chip mounting is resorted to, the amount of heat generated increases on account of the greater number of terminals, and the heat dissipation effect of the present embodiment is more pronounced.

### Embodiment 2

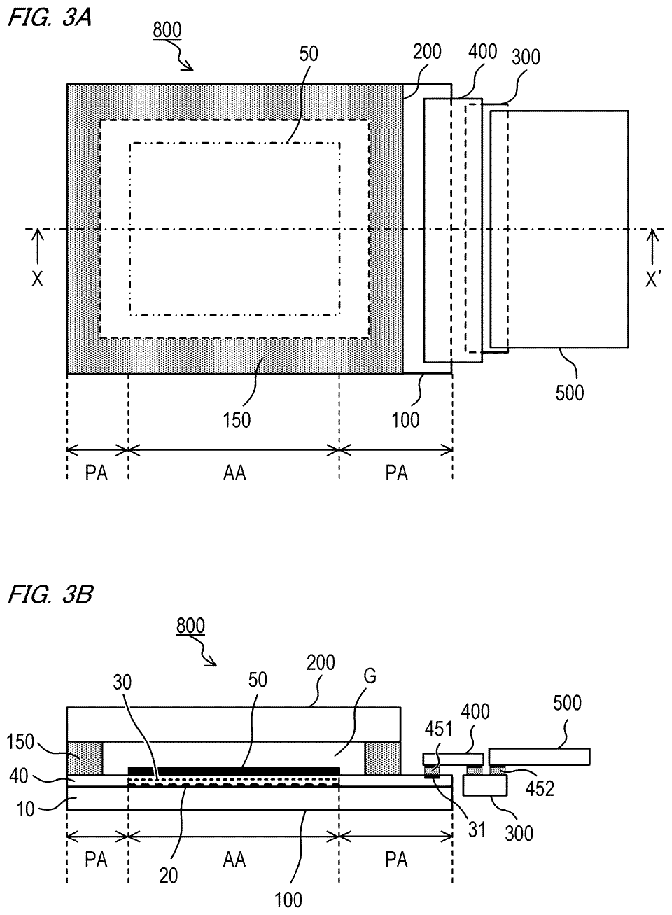

A semiconductor device 800 according to Embodiment 2 will be explained with reference to FIG. 3A and FIG. 3B. Unlike Embodiment 1, herein the wiring board 500 is connected not to the wiring board 400, but to the drive circuit chip 300. That is, the wiring board 400 is connected to the element substrate 100 and one electrode (terminal portion) of the drive circuit chip 300, while the wiring board 500 is connected to another electrode of the drive circuit chip 300. Explanations overlapping those pertaining to Embodiment 1 will be omitted. FIG. 3A illustrates a plan-view diagram of the semiconductor device 800 according to Embodiment 2, with the main surface of the element substrate 100 seen in a plan view. FIG. 3B is an X-X′ cross-sectional diagram of the semiconductor device 800 illustrated in FIG. 3A.

As illustrated in FIG. 3A, the wiring board 400 is connected to one electrode of the drive circuit chip 300; thus, the wiring board 400 can be made smaller than in a case where the wiring board 400 is connected both the drive circuit chip 300 and the wiring board 500, as in Embodiment 1. As in the case of Embodiment 1, the semiconductor device 800 according to Embodiment 2 allows reducing deterioration of characteristics caused by heat, and reducing the manufacturing cost of the wiring board 400.

### Embodiment 3

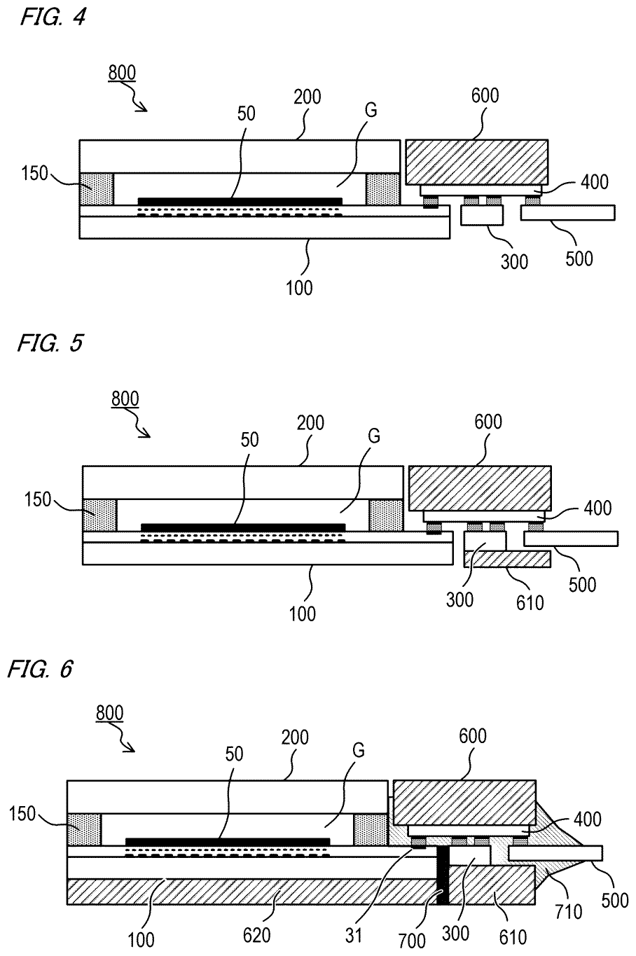

A semiconductor device 800 according to Embodiment 3 will be explained with reference to FIG. 4. Unlike Embodiment 1, herein a heat dissipation member 600 is provided on the surface of the wiring board 400 having no electrode (terminal portion) formed thereon. The surface of the wiring board 400 having no electrode formed thereon is the surface on the reverse side from that of the surface connected to the element substrate 100, the drive circuit chip 300 and the wiring board 500. Explanations overlapping those pertaining to Embodiment 1 will be omitted.

The heat dissipation member 600 is for instance a metallic heat dissipation fin, of aluminum or copper, or a heat dissipation film capable of efficiently dumping heat into the atmosphere. The heat dissipation member 600 is bonded to the wiring board 400 using an adhesive having high thermal conductivity, preferably an adhesive containing a silver filler.

The semiconductor device 800 according to Embodiment 3 can efficiently dump heat from the drive circuit chip 300 to the atmosphere, through the wiring board 400 and the heat dissipation member 600. Therefore, the semiconductor device 800 according to Embodiment 3 allows further reducing transfer of heat from the drive circuit chip 300 to the element substrate 100, and allows further extending the life of for instance an organic EL display device that utilizes the semiconductor device 800, as compared with the case of Embodiment 1.

### Embodiment 4

A semiconductor device 800 according to Embodiment 4 will be explained with reference to FIG. 5. Unlike Embodiment 3, herein a heat dissipation member 610 is provided on the surface of the drive circuit chip 300 having no electrode (terminal portion) formed thereon. The surface of the drive circuit chip 300 having no electrode formed thereon is the surface on the reverse side from that connected to the wiring board 400. Explanations overlapping those pertaining to Embodiment 3 will be omitted.

The same member as the heat dissipation member 600 of Embodiment 3 can be used herein as the heat dissipation member 610. Also, the heat dissipation member 610 can be bonded to the drive circuit chip 300 in accordance with the same method as the method for bonding the heat dissipation member 600 to the wiring board 400 in Embodiment 3. The heat dissipation member 610 is installed independently of the heat dissipation member 600. FIG. 5 illustrates an example in which the heat dissipation member 600 and the heat dissipation member 610 are both installed, but also the heat dissipation member 610 may be installed while the heat dissipation member 600 is not.

The semiconductor device 800 according to Embodiment 4 can also dump heat from the heat dissipation member 610 installed on the drive circuit chip 300. Therefore, the semiconductor device 800 according to Embodiment 4 allows further reducing transfer of heat from the drive circuit chip 300 to the element substrate 100, and allows further extending the life of for instance an organic EL display device that utilizes the semiconductor device 800, as compared with the case of Embodiment 3.

### Embodiment 5

A semiconductor device 800 according to Embodiment 5 will be explained with reference to FIG. 6. Unlike Embodiment 4, herein a heat dissipation member 620 is installed on the surface, of the element substrate 100, on which the terminal portion 31 is not formed. The surface of the element substrate 100 on which the terminal portion 31 is not formed is the surface on the reverse side from that connected to the wiring board 400. Explanations overlapping those pertaining to Embodiment 4 will be omitted.

The same member as the heat dissipation member 600 of Embodiment 3 can be used herein as the heat dissipation member 620. Also, the heat dissipation member 620 can be bonded to the element substrate 100 in accordance with the same method as the method for bonding the heat dissipation member 600 to the wiring board 400 in Embodiment 3. The heat dissipation member 620 is installed independently of the heat dissipation member 600 and the heat dissipation member 610. FIG. 6 illustrates an example in which the heat dissipation members 600, 610, 620 are installed, but alternatively the heat dissipation member 620 may be installed, while at least one from among the heat dissipation member 600 and the heat dissipation member 610 is not installed.

A reinforcing member 700 may be disposed between the element substrate 100 and the drive circuit chip 300. A reinforcing member 710 may be provided so as to fill the space between the element substrate 100, the wiring board 400, the drive circuit chip 300 and the wiring board 500. The mechanical strength of the semiconductor device 800 according to Embodiment 5 can be increased by providing the reinforcing member 700 and the reinforcing member 710.

Transfer of heat from the drive circuit chip 300 to the element substrate 100 is further reduced by using a thermal insulation material as the material of the reinforcing member 700 and of the reinforcing member 710. Therefore, the semiconductor device 800 according to Embodiment 5 has higher mechanical strength, and allows further reducing transfer of heat to the element substrate 100, than in the case of Embodiment 4.

The reinforcing member 700 and the reinforcing member 710 may be provided in the semiconductor device 800 according to Embodiment 3 and Embodiment 4, similarly to Embodiment 5. The mechanical strength of the semiconductor device 800 according to Embodiment 3 and Embodiment 4 can be increased by providing the reinforcing member 700 and the reinforcing member 710.

### Embodiment 6

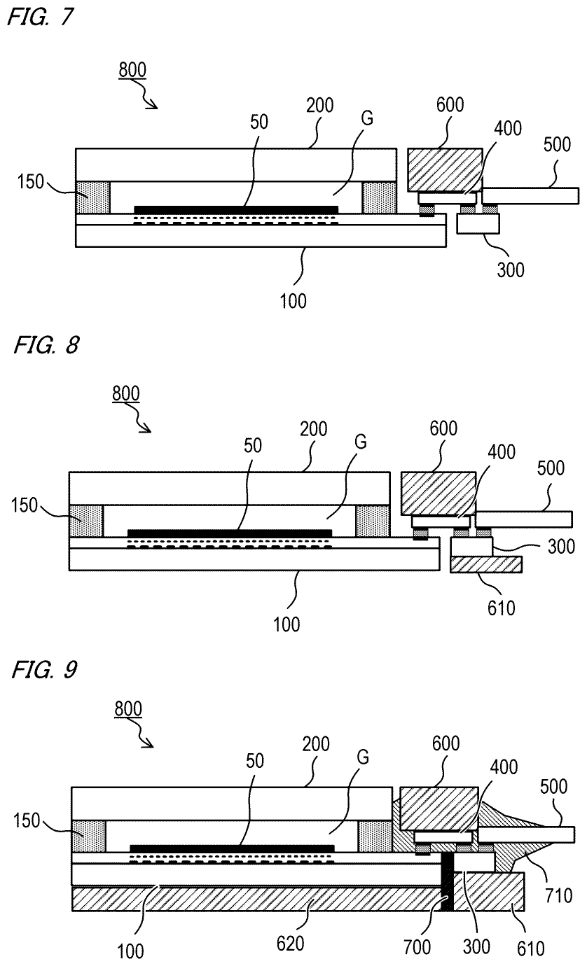

A semiconductor device 800 according to Embodiment 6 will be explained with reference to FIG. 7. Embodiment 6 is an embodiment where the heat dissipation member 600 in the semiconductor device 800 according to Embodiment 2 is installed on the surface, of the wiring board 400, having no electrode (terminal portion) formed thereon. The surface of the wiring board 400 having no electrode formed thereon is the surface on the reverse side from that connected to the element substrate 100 and the drive circuit chip 300. Explanations overlapping those pertaining to Embodiment 2 will be omitted.

The same member as the heat dissipation member 600 of Embodiment 3 can be used as the heat dissipation member 600 of Embodiment 6, and can be bonded to the wiring board 400 in accordance with the same method as in Embodiment 3.

In the semiconductor device 800 according to Embodiment 6, the wiring board 400 can be made smaller, and heat from the drive circuit chip 300 can be dumped more efficiently to the atmosphere through the wiring board 400 and the heat dissipation member 600, than in the case of Embodiment 1. Therefore, the semiconductor device 800 according to Embodiment 6 allows reducing transfer of heat from the drive circuit chip 300 to the element substrate 100 at a lower cost, and allows further extending the life of for instance an organic EL display device that utilizes the semiconductor device 800, than in the case of Embodiment 3.

### Embodiment 7

A semiconductor device 800 according to Embodiment 7 will be explained with reference to FIG. 8. Unlike Embodiment 6, herein the heat dissipation member 610 is provided on the surface, of the drive circuit chip 300, having no electrode (terminal portion) formed thereon. The surface of the drive circuit chip 300 having no electrode formed thereon is the surface on the reverse side from that connected to the wiring board 400 and the wiring board 500. Explanations overlapping those pertaining to Embodiment 6 will be omitted.

The same member as the heat dissipation member 600 of Embodiment 3 can be used herein as the heat dissipation member 610. Also, the heat dissipation member 610 can be bonded to the drive circuit chip 300 in accordance with the same method as the method for bonding the heat dissipation member 600 to the wiring board 400 in Embodiment 3. The heat dissipation member 610 is installed independently of the heat dissipation member 600. FIG. 8 illustrates an example in which the heat dissipation member 600 and the heat dissipation member 610 are both installed, but also the heat dissipation member 610 may be installed while the heat dissipation member 600 is not.

The semiconductor device 800 according to Embodiment 7 can also dump heat from the heat dissipation member 610 installed on the drive circuit chip 300. Therefore, the semiconductor device 800 according to Embodiment 4 allows further reducing transfer of heat from the drive circuit chip 300 to the element substrate 100, and allows further extending the life of for instance an organic EL display device that utilizes the semiconductor device 800, than in the case of Embodiment 6.

### Embodiment 8

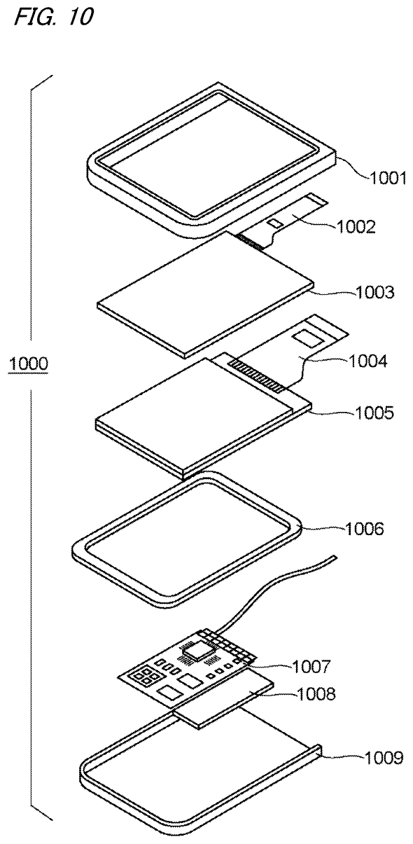

A semiconductor device 800 according to Embodiment 8 will be explained next with reference to FIG. 9. Unlike Embodiment 7, herein a heat dissipation member 620 is installed on the surface, of the element substrate 100, on which the terminal portion 31 is not formed. The surface of the element substrate 100 on which the terminal portion 31 is not formed is the surface on the reverse side from that connected to the wiring board 400. Explanations overlapping those pertaining to Embodiment 7 will be omitted.

The same member as the heat dissipation member 600 of Embodiment 3 can be used herein as the heat dissipation member 620. Also, the heat dissipation member 620 can be bonded to the element substrate 100 in accordance with the same method as the method for bonding the heat dissipation member 600 to the wiring board 400 in Embodiment 3. The heat dissipation member 620 is installed independently of the heat dissipation member 600 and the heat dissipation member 610. FIG. 9 illustrates an example in which the heat dissipation members 600, 610, 620 are installed, but alternatively the heat dissipation member 620 may be installed, while at least one from among the heat dissipation member 600 and the heat dissipation member 610 is not installed.

The reinforcing member 700 may be disposed between the element substrate 100 and the drive circuit chip 300. The reinforcing member 710 may be provided so as to fill the space between the element substrate 100, the wiring board 400, the drive circuit chip 300 and the wiring board 500. The mechanical strength of the semiconductor device 800 according to Embodiment 8 can be increased by providing the reinforcing member 700 and the reinforcing member 710.

Transfer of heat from the drive circuit chip 300 to the element substrate 100 is further reduced by using a thermal insulation material as the material of the reinforcing member 700 and of the reinforcing member 710. Therefore, the semiconductor device 800 according to Embodiment 8 has higher mechanical strength, and allows further reducing transfer of heat to the element substrate 100, than in the case of Embodiment 7.

The reinforcing member 700 and the reinforcing member 710 may be provided in the semiconductor device 800 according to Embodiment 6 and Embodiment 7, similarly to Embodiment 8. The mechanical strength of the semiconductor device 800 according to Embodiment 6 and Embodiment 7 can be increased by providing the reinforcing member 700 and the reinforcing member 710.

### Embodiment 9

In Embodiment 9 examples will be explained in which the semiconductor device 800 according to Embodiments 1 to 8 is applied to various devices. In a case where the semiconductor device 800 is used in a display device, the element substrate 100 is a display element substrate, and a light-emitting element is disposed in the effective pixel area AA. In a case where the semiconductor device 800 is used in an imaging device, the element substrate 100 is an imaging element substrate, and an imaging element is disposed in the effective pixel area AA.

FIG. 10 is a schematic diagram illustrating a display device 1000 being an example of a display device according to the present embodiment. The display device 1000 may have a touch panel 1003, a display panel 1005, a frame 1006, a circuit board 1007 and a battery 1008, between an upper cover 1001 and a lower cover 1009.

The display panel 1005 is a display unit having the semiconductor device 800 according to Embodiments 1 to 8 and which performs display using light emitted from the semiconductor device 800. Flexible printed circuits FPC 1002, 1004 are connected to the touch panel 1003 and the display panel 1005. A control circuit including transistors and that is printed on the circuit board 1007 executes various control tasks, such as control of the display panel 1005. The battery 1008 may be omitted if the display device is not a portable device, or even if the display device is a portable device, the battery 1008 may be provided at a different position. The display device 1000 may have three types of color filters, respectively corresponding to red, green and blue. A plurality of color filters may be disposed in a delta arrangement.

The display device 1000 may be used as a display unit of a mobile terminal. In that case the display device 1000 may have both a display function and an operation function. Mobile terminals include mobile phones such as smartphones, tablets and head-mounted displays.

The display device 1000 may be used in a display unit of an imaging device that has an optical member provided with a plurality of lenses, and that has an imaging element that receives light having passed through the optical member. The imaging device may have a display unit that displays information acquired by the imaging element (for instance an image captured by the imaging element). The display unit may be a display unit exposed to the exterior of the imaging device, or may be a display unit disposed within a viewfinder. The imaging device may be for instance a digital camera or a digital video camera.

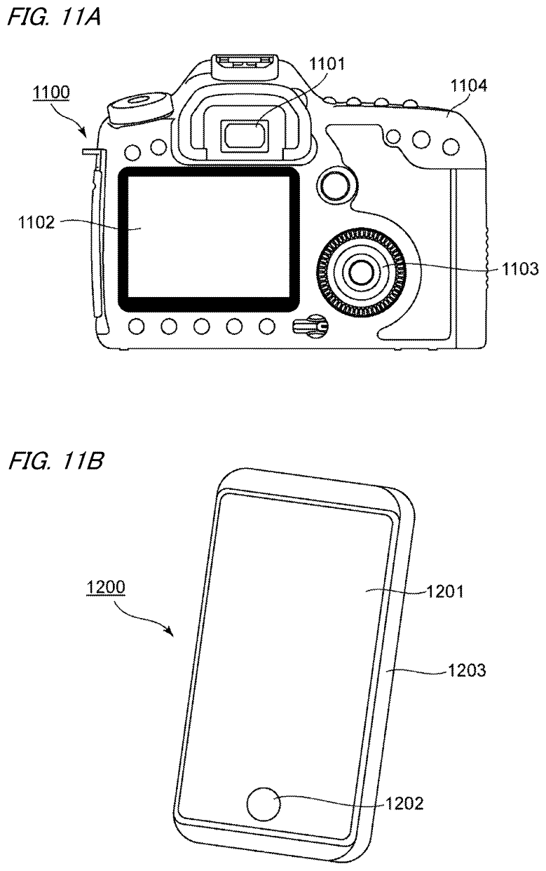

FIG. 11A is a schematic diagram illustrating an imaging device 1100, being an example of an imaging device according to the present embodiment. The imaging device 1100 may have a viewfinder 1101, a rear display 1102, an operation unit 1103 and a housing 1104. The viewfinder 1101 may have the display device according to the present embodiment (display device having the semiconductor device 800 according to Embodiments 1 to 8 and which performs display using light emitted from the semiconductor device 800). In that case the display device may display not only an image to be captured, but also for instance environment information and imaging instructions. The environment information may include for instance external light intensity, external light orientation, moving speed of a subject, and the chance of the subject being blocked by an obstacle. The rear display 1102 may also have a display device according to the present embodiment.

The timing suitable for imaging is herein short, and hence information should be displayed as soon as possible. Therefore, a display device is preferably used that utilizes organic light-emitting elements having high response speed. A display device that utilizes organic light-emitting elements can be utilized more suitably than for instance a liquid crystal display device, in a device from which a high display speed is required.

The imaging device 1100 has an optical member (not shown). The optical member has a plurality of lenses, and forms an image of light on an imaging element accommodated in the housing 1104. The lenses can be focused through adjustment of the relative positions thereof. This operation can also be performed automatically. The imaging device 1100 may be referred to as a photoelectric conversion device. The photoelectric conversion device can encompass, as an imaging method other than sequential imaging, a method that involves detecting a difference relative to a previous image or a method that involves cutting out part of a recorded image.

FIG. 11B is a schematic diagram illustrating an electronic device 1200 being an example of an electronic device according to the present embodiment. The electronic device 1200 has a display unit 1201, an operation unit 1202 and a housing 1203. The display unit 1201 has the semiconductor device 800 according to Embodiments 1 to 8, and performs display using light emitted from the semiconductor device 800. The electronic device 1200 may include, in the housing 1203, a circuit, a printed board having the circuit, a battery and a communication interface for communication with the exterior. The operation unit 1202 may be a button, or a touch panel-type reaction unit. The operation unit may be a biometric recognition unit which for instance performs unlocking upon recognition of a fingerprint. The electronic device having a communication interface can also be referred to as a communication device. The electronic device may further have a camera function, by being provided with a lens and an imaging element. Images captured by way of the camera function are displayed on the display unit. Examples of the electronic device include smartphones and notebook computers.

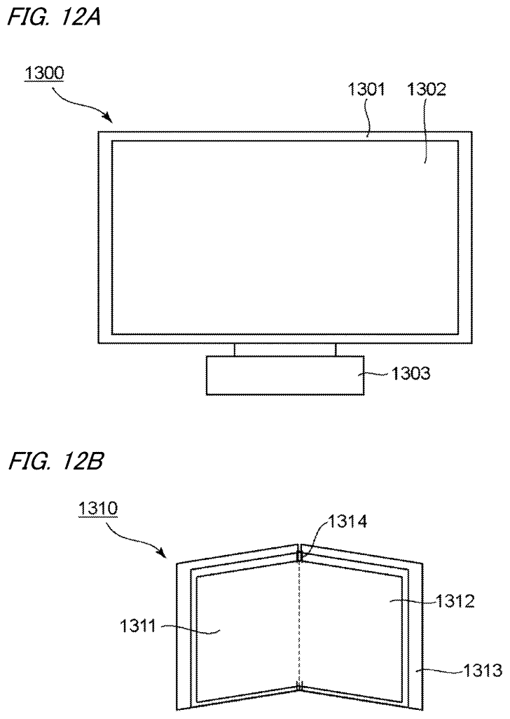

FIG. 12A and FIG. 12B are schematic diagrams illustrating a display device 1300, being an example of a display device according to the present embodiment. The display device 1300 is a display device such as a television monitor or a PC monitor. The display device 1300 has a frame 1301, a display unit 1302, and a base 1303 that supports the frame 1301 and the display unit 1302. The display unit 1302 has the semiconductor device 800 according to Embodiments 1 to 8, and performs display using light emitted from the semiconductor device 800. The form of the base 1303 is not limited to the form in FIG. 12A. The lower side of the frame 1301 may also double as the base 1303. The frame 1301 and the display unit 1302 may be curved. The radius of curvature of the foregoing may be at least 5000 mm and not more than 6000 mm. FIG. 12B is a schematic diagram illustrating a display device 1310 being an example of another display device according to the present embodiment. The display device 1310 is a so-called foldable display device, configured to be foldable. The display device 1310 has a first display unit 1311, a second display unit 1312, a housing 1313 and a folding point 1314. The first display unit 1311 and the second display unit 1312 each has the semiconductor device 800 according to Embodiments 1 to 8, and performs display using light emitted from the semiconductor device 800. The first display unit 1311 and the second display unit 1312 may be one seamless display device. The first display unit 1311 and the second display unit 1312 can be separated at the folding point. The first display unit 1311 and the second display unit 1312 may display different images; alternatively, the first display unit 1311 and the second display unit 1312 may display one image.

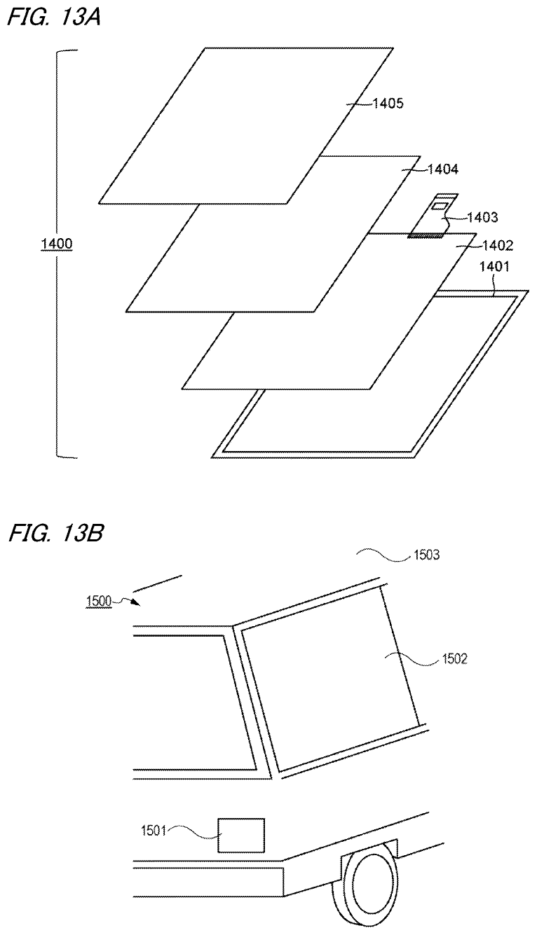

FIG. 13A is a schematic diagram illustrating a lighting device 1400 being an example of a lighting device according to the present embodiment. The lighting device 1400 may have a housing 1401, a light source 1402, a circuit board 1403, an optical film 1404 and a light diffusion part 1405. The light source 1402 has the semiconductor device 800 according to Embodiments 1 to 8. The optical film 1404 may be a filter (optical filter) for improving the color rendering properties of the light source 1402. The light diffusion part 1405 allows effectively diffusing light from the light source 1402 and allows delivering light over a wide area, for instance in exterior decorative lighting. The optical film 1404 and the light diffusion part 1405 may be provided on the light exit side of the lighting device 1400. A cover may be provided on the outermost part, as the case may require.

The lighting device 1400 is for instance a device for indoor illumination. The lighting device 1400 may emit white, daylight white, or other colors (any color from blue to red). White is herein a color with a color temperature of 4200 K, and daylight white is a color with a color temperature of 5000 K. The lighting device 1400 may have a light control circuit for controlling the emission color of the lighting device 1400. The lighting device 1400 may have a power supply circuit connected to the light source 1402. The power supply circuit is a circuit that converts AC voltage to DC voltage. The lighting device 1400 may also have a color filter. The lighting device 1400 may have a heat dissipation part. The purpose of the heat dissipation part is to dump, to the exterior, heat from inside the device; the heat dissipation part may be made up of a metal or of liquid silicone rubber, exhibiting high specific heat.

FIG. 13B is a schematic diagram illustrating an automobile 1500, being an example of a moving body according to the present embodiment. The automobile 1500 may have a tail lamp 1501, being an example of a lamp. The tail lamp 1501 lights up for instance in response to a braking operation.

The tail lamp 1501 has the semiconductor device 800 according to Embodiments 1 to 8. The tail lamp 1501 may have a protective member that protects the semiconductor device 800. The protective member may be made up of any material, provided that the material has a certain degree of strength and is transparent; the protective member is preferably made up of polycarbonate or the like. For instance a furandicarboxylic acid derivative or an acrylonitrile derivative may be mixed with the polycarbonate.

The automobile 1500 may have a vehicle body 1503 and a window 1502 attached to the vehicle body 1503. The window 1502 may be a transparent display, unless the window 1502 is a window for looking ahead and behind the automobile 1500. The transparent display may have the semiconductor device 800 according to Embodiments 1 to 8. In that case, constituent materials such as the electrodes of the semiconductor device 800 are made up of transparent members.

The moving body according to the present embodiment may be for instance a vessel, an aircraft or a drone. The moving body may have a body frame and a lamp provided on the body frame. The lamp may emit light to indicate the position of the body frame. The lamp has the semiconductor device 800 according to Embodiments 1 to 8.

The display device according to the present embodiment (display device having the semiconductor device 800 according to Embodiments 1 to 8 and which performs display using light emitted from the semiconductor device 800) can be used for instance in a wearable device such as smart glasses, HMDs or smart contacts. The display device according to the present embodiment can also be applied to a system having for instance a wearable device. An imaging display device used for instance as a wearable device has an imaging device capable of photoelectrically converting visible light, and a display device capable of emitting visible light.

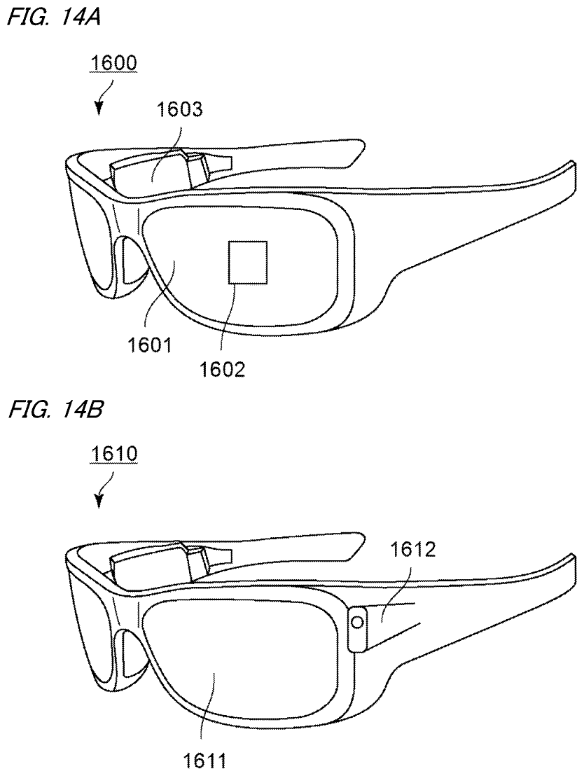

FIG. 14A is a schematic diagram illustrating spectacles 1600 (smart glasses) being an example of a wearable device according to the present embodiment. An imaging device 1602 such as a CMOS sensor or an SPAD is provided on the front surface side of a lens 1601 of the spectacles 1600. A display device according to the present embodiment (display device having the semiconductor device 800 according to Embodiments 1 to 8 and that performs display using light emitted from the semiconductor device 800) is provided on the rear surface side of the lens 1601.

The spectacles 1600 further have a control device 1603. The control device 1603 functions as a power source that supplies power to the imaging device 1602 and the above display device. The control device 1603 controls the operations of the imaging device 1602 and of the display device. The lens 1601 has formed therein an optical system for condensing light onto the imaging device 1602.

FIG. 14B is a schematic diagram illustrating spectacles 1610 (smart glasses) being an example of a wearable device according to the present embodiment. The spectacles 1610 have a control device 1612, the control device 1612 having mounted thereon an imaging device corresponding to the imaging device 1602, and the display device according to the present embodiment. In a lens 1611 there are formed an imaging device within the control device 1612 and an optical system for projecting the light emitted from the display device, such that an image is projected onto the lens 1611. The control device 1612 functions as a power source that supplies power to the imaging device and the display device, and also controls the operations of the imaging device and of the display device.

The control device may have a line-of-sight detection unit that detects the line of sight of the wearer of the spectacles 1610. Infrared rays may be used herein for line-of-sight detection. An infrared light-emitting unit emits infrared light towards one eyeball of a user who is gazing at a display image. The light emitted is reflected by the eyeball, and is detected by an imaging unit having a light-receiving element, whereby a captured image of the eyeball is obtained as a result. Drops in the quality of the image projected from the display device onto the lens 1611 are reduced herein by having a reduction unit that reduces light from the infrared light-emitting unit to the display unit in a plan view. The control device detects the line of sight of the user with respect to the display image on the basis of the captured image of the eyeball obtained through infrared light imaging. Any known method can be resorted to for line-of-sight detection using the captured image of the eyeball. As an example, a line-of-sight detection method can be resorted to that utilizes a Purkinje image obtained by reflection of irradiation light on the cornea. More specifically, line-of-sight detection processing based on a pupillary-corneal reflection method is carried out herein. The line of sight of the user is detected by calculating a line-of-sight vector that denotes the orientation (rotation angle) of the eyeball, on the basis of a Purkinje image and a pupil image included in the captured image of the eyeball, in accordance with a pupillary-corneal reflection method.

In a case where display control is performed on the basis of visual recognition detection (line-of-sight detection), the semiconductor device 800 according to Embodiments 1 to 8 can be preferably used in smart glasses having an imaging device that captures images of the exterior. The smart glasses can display captured external information in real time.

The display device according to the present embodiment (display device including the semiconductor device 800 according to Embodiments 1 to 8 and which performs display using light emitted from the semiconductor device 800) may include an imaging device having a light-receiving element, such that the display image is controlled on the basis of line-of-sight information of the user from the imaging device. Specifically, a first visual field area gazed at by the user and a second visual field area, other than the first visual field area, are determined on the basis of line-of-sight information. The first visual field area and the second visual field area may be determined by the control device of the display device; alternatively, the display device may receive visual field areas determined by an external control device. In the display area of the display device, the display resolution in the first visual field area may be controlled to be higher than the display resolution in the second visual field area. That is, the resolution in the second visual field area may set to be lower than that of the first visual field area.

The display area may have a first display area and a second display area different from the first display area, with the higher priority area from among the first display area and the second display area being determined on the basis of line-of-sight information. The first display area and the second display area may be determined by the control device of the display device; alternatively, the display device may receive display areas determined by an external control device. The resolution in areas with high priority may be controlled so as to be higher than the resolution in areas other than high-priority areas. That is, the resolution in areas of relatively low priority may be set to be lower.

Herein AI may be used to determine the first visual field area and high-priority areas. The AI may be a model constructed to estimate a line-of-sight angle, from an eyeball image, and the distance to an object lying ahead in the line of sight, using training data in the form of the image of the eyeball and the direction towards which the eyeball in the image was actually gazing at. An AI program may be provided in the display device, in the imaging device, or in an external device. In a case where the AI program is in the external device, the AI program is transmitted to the display device via communication.

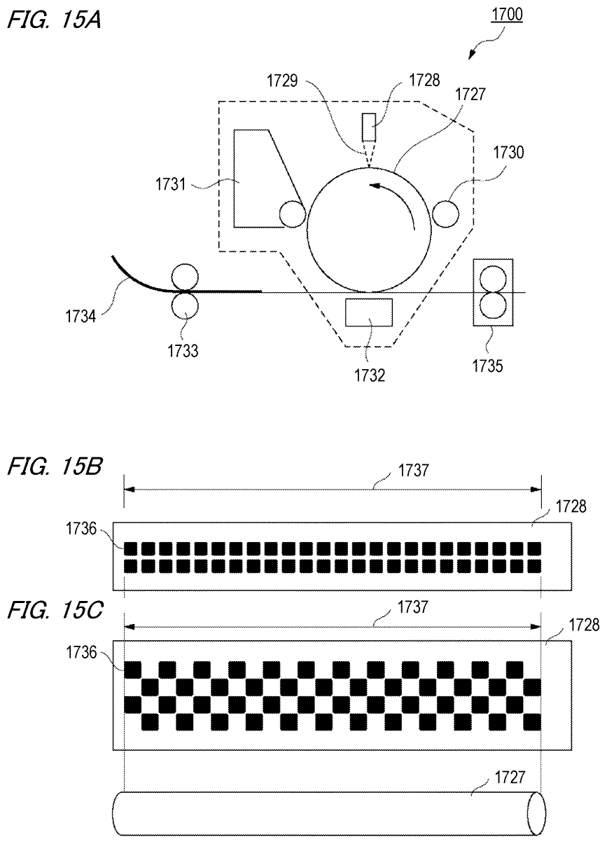

FIG. 15A is a schematic diagram illustrating an image forming apparatus 1700, being an example of an image forming apparatus according to the present embodiment. The image forming apparatus 1700 has a photosensitive member 1727, an exposure light source 1728, a charging unit 1730, a developing unit 1731, a transfer device 1732, transport rollers 1733 and a fixing unit 1735.

Light 1729 is emitted from the exposure light source 1728, whereupon an electrostatic latent image becomes formed on the surface of the photosensitive member 1727. The semiconductor device 800 according to Embodiments 1 to 8 can be used in the exposure light source 1728. The developing unit 1731 has for instance a toner, and causes the toner to adhere to the electrostatic latent image formed on the surface of the photosensitive member 1727. The charging unit 1730 charges the photosensitive member 1727. The transfer device 1732 transfers a developed image to a recording medium 1734. The transport rollers 1733 transport the recording medium 1734. The recording medium 1734 is for instance paper. The fixing unit 1735 fixes the image formed on the recording medium.

FIG. 15B and FIG. 15C are schematic diagrams illustrating an exposure light source 1728 in which multiple light-emitting units 1736 are disposed on an elongated substrate. The light-emitting units 1736 have an organic light-emitting element. The light-emitting units 1736 may have a plurality of organic light-emitting elements. In a case where the semiconductor device 800 according to Embodiments 1 to 8 is used in the exposure light source 1728, the multiple light-emitting units 1736 are disposed in the effective pixel area AA. In the exposure light source 1728, the element substrate 100 having the light-emitting units 1736 is connected to the drive circuit chip 300 via the wiring board 400.

The arrow 1737 denotes a direction parallel to the axis of the photosensitive member, and denotes a column direction in which the light-emitting units 1736 are arrayed. The column direction denoted by the arrow 1737 is the same direction as the rotation axis of the photosensitive member 1727, and can also be referred to as the long axis direction of the photosensitive member 1727.

FIG. 15B illustrates an exposure light source 1728 of a form in which the light-emitting units 1736 are arrayed in two rows along the long axis direction of the photosensitive member 1727. FIG. 15C illustrates a form of the exposure light source 1728 different from that of FIG. 15B. In the exposure light source 1728 of FIG. 15B, the light-emitting units 1736 are lined up in four rows spaced apart from each other. Specifically, the light-emitting units 1736 are disposed in the first and third rows, in odd-numbered columns, and are disposed in the second and fourth rows, in even-numbered columns. The arrangement of the light-emitting units 1736 in FIG. 15C is a grid arrangement, also called a houndstooth or checkered arrangement.

As explained above, various devices can stably display images with good image quality, over long periods of time, through the use of the semiconductor device 800 according to Embodiments 1 to 8.

The functional units (configurations) of the various devices explained in Embodiment 9 may or may not be individual pieces of hardware. Functions of two or more functional units may be realized by shared hardware. Each of multiple functions of one functional unit may be implemented by separate pieces of hardware. Two or more functions of one functional unit may be realized by shared hardware. The functional units may or may not be realized by hardware such as ASICs, FPGAs and DSPs. For instance, the device may have a processor and a memory (storage medium) in which a control program is stored. The functions of at least some of the functional units of the device may be realized in that the processor reads out a control program from the memory, and executes the control program.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

The present invention provides a technique for reducing transfer of heat from a drive circuit chip to an element substrate of a semiconductor device, and reducing deterioration of the characteristics of the semiconductor device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-092935, filed on Jun. 8, 2022, which is hereby incorporated by reference herein in its entirety.

What is claimed is:

1. A semiconductor device, comprising:
a substrate having an effective element area on which a functional element is disposed, and a peripheral area that surrounds the effective element area, the substrate having a terminal portion in at least a portion of the peripheral area;
a first wiring board connected to the substrate via the terminal portion of the substrate; and
a drive circuit chip having a drive circuit, and connected to the first wiring board, wherein
a thermal conductivity of the first wiring board is equal to or higher than a thermal conductivity of the substrate and of the drive circuit chip.

2. The semiconductor device of claim 1, comprising:
a second wiring board connected to the first wiring board, wherein
the substrate, the drive circuit chip and the second wiring board are disposed so that surfaces thereof joined to the first wiring board is a common plane, and are connected to each other by the first wiring board.

3. The semiconductor device of claim 1, wherein
the first wiring board is joined to the substrate and the drive circuit chip by thermocompression joining using an anisotropic conductive film, by solder joining or by ultrasonic joining.

4. The semiconductor device of claim 1, wherein
the first wiring board is formed of a metallic material including gold, silver, copper or aluminum, a ceramic material including aluminum nitride or silicon nitride, or silicon.

5. The semiconductor device of claim 1, wherein
a heat dissipation member is installed on a surface, of the first wiring board, having no electrode formed thereon.

6. The semiconductor device of claim 1, wherein
a heat dissipation member is installed on a surface, of the drive circuit chip, having no electrode formed thereon.

7. The semiconductor device of claim 1, wherein
a heat dissipation member is installed on a surface, of the substrate, having no terminal portion formed thereon.

8. The semiconductor device of claim 1, comprising:
at least one of a reinforcing member disposed between the substrate and the drive circuit chip, and a reinforcing member provided so as to fill a space between the substrate, the first wiring board and the drive circuit chip.

9. The semiconductor device of claim 1, comprising:
a second wiring board connected to the first wiring board or the drive circuit chip; and
at least either one of a reinforcing member disposed between the substrate and the drive circuit chip, and a reinforcing member provided so as to fill a space between the substrate, the first wiring board, the drive circuit chip and the second wiring board.

10. The semiconductor device of claim 8, wherein
the reinforcing member is formed by using a thermal insulation material.

11. The semiconductor device of claim 1, comprising:
a second wiring board connected to the drive circuit chip; wherein
the first wiring board and the second wiring board are disposed so that surfaces thereof joined to the drive circuit chip is a common plane, and are connected to each other by the drive circuit chip.

12. A display device, comprising:
a display unit having the semiconductor device of claim 1; and
a control circuit that controls the display unit.

13. A photoelectric conversion device, comprising:
an optical member;
an imaging element that receives light passing through the optical member; and
a display unit that displays an image captured by the imaging element, wherein
the display unit has the semiconductor device of claim 1.

14. An electronic device, comprising:
a display unit having the semiconductor device of claim 1;
a housing in which the display unit is provided; and
a communication interface, provided in the housing, and that communicates with the exterior.

15. An image forming apparatus, comprising:
a light source having the semiconductor device of claim 1;
a developing unit irradiated by the light source, and in which toner is caused to adhere to an electrostatic latent image formed on the surface of a photosensitive member; and
a transfer device that transfers, to a recording medium, an image developed by the developing unit.
